(19) United States
(12) Patent Application Publication
(10) Pub. No.: US 2026/0323925 A1
(43) Pub. Date: Oct. 15, 2026

(54) SPACER STRUCTURE, SEMICONDUCTOR DEVICE COMPRISING THE SAME, AND METHOD FOR FABRICATING THE SAME

(71) Applicant: NANYA TECHNOLOGY CORPORATION, NEW TAIPEI CITY (TW)

(72) Inventor: WEI-CHUAN FANG, NEW TAIPEI CITY (TW)

(21) Appl. No.: 19/174,181

(22) Filed: Apr. 9, 2025

(51) Int. Cl. H10B 12/00

(52) U.S. Cl. CPC H10B 12/485; H10B 12/0335

(57) ABSTRACT

The present application discloses a spacer structure, a semiconductor device with the same, and a method for fabricating the semiconductor device with the same. The spacer structure includes an inner spacer positioned on a side of a bit line structure, wherein the inner spacer includes silicon oxycarbide; a middle spacer positioned on the inner spacer; and an outer spacer positioned on the middle spacer.

### TECHNICAL FIELD

The present disclosure relates to a spacer structure, a semiconductor device comprising the same, and a method for fabricating the semiconductor device comprising the spacer structure, and more particularly, to a spacer structure comprising silicon oxycarbide, a semiconductor device with the spacer structure, and a method for fabricating the semiconductor device comprising the spacer structure.

### DISCUSSION OF THE BACKGROUND

Semiconductor devices are used in a variety of electronic applications, such as personal computers, cellular telephones, digital cameras, and other electronic equipment. The dimensions of semiconductor devices are continuously being scaled down to meet the increasing demand of computing ability. However, a variety of issues arise during the scaling-down process, and such issues are continuously increasing. Therefore, challenges remain in achieving improved quality, yield, performance, and reliability and reduced complexity.

This Discussion of the Background section is provided for background information only. The statements in this Discussion of the Background are not an admission that the subject matter disclosed in this section constitutes prior art to the present disclosure, and no part of this Discussion of the Background section may be used as an admission that any part of this application, including this Discussion of the Background section, constitutes prior art to the present disclosure.

### SUMMARY

One aspect of the present disclosure provides a spacer structure including an inner spacer positioned on a sides of a bit line structure, wherein the inner spacer includes silicon oxycarbide; a middle spacer positioned on the inner spacer; and an outer spacer positioned on the middle spacer.

Another aspect of the present disclosure provides a semiconductor device including a substrate; a bit line structure positioned on the substrate; a spacer structure including an inner spacer conformally positioned on a side of the bit line structure, a middle spacer conformally positioned on the inner spacer, and an outer spacer conformally positioned on the middle spacer. The inner spacer includes silicon oxycarbide.

Another aspect of the present disclosure provides a method for fabricating a semiconductor device including providing a substrate; forming a plurality of bit line contact structures in the substrate; forming a plurality of bit line structures on the plurality of bit line contact structures, wherein the plurality of bit line structures are separated by a plurality of trenches and a plurality of recesses that extend downward from the trenches and are adjacent to the bit line contact structures; conformally forming a layer of first spacer material covering the plurality of bit line structures, the plurality of bit line contact structures, the plurality of trenches, and the plurality of recesses; forming a plurality of filling layers to fill the plurality of recesses; conformally forming a layer of second spacer material covering the layer of first spacer material and the plurality of filling layers; performing a first spacer etching process to turn the layer of first spacer material into a plurality of inner spacers and turn the layer of second spacer material into a plurality of middle spacers; and conformally forming a plurality of outer spacers on the plurality of middle spacers to configure a plurality of spacer structures. The first spacer material includes silicon oxycarbide.

Due to the design of the semiconductor device of the present disclosure, the inner spacer, formed of silicon oxycarbide, can effectively protect the bit line structures during subsequent etching processes. Its strong chemical resistance helps reduce defects such as bit line leakage, thereby improving the yield of the semiconductor device. Additionally, the low dielectric constant of the silicon oxycarbide inner spacer may reduce parasitic capacitance between adjacent bit line structures, enhancing the overall performance of the semiconductor device.

The foregoing has outlined rather broadly the features and technical advantages of the present disclosure in order that the detailed description of the disclosure that follows may be better understood. Additional features and advantages of the disclosure will be described hereinafter, and form the subject of the claims of the disclosure. It should be appreciated by those skilled in the art that the conception and specific embodiment disclosed may be readily utilized as a basis for modifying or designing other structures or processes for carrying out the same purposes of the present disclosure. It should also be realized by those skilled in the art that such equivalent constructions do not depart from the spirit and scope of the disclosure as set forth in the appended claims.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIG. 1 illustrates, in a flowchart diagram form, a method for fabricating a semiconductor device in accordance with one embodiment of the present disclosure;

FIG. 2 illustrates, in a schematic top-view diagram, an intermediate semiconductor device in accordance with one embodiment of the present disclosure;

FIGS. 3 and 4 are schematic cross-sectional view diagrams taken along lines A-A′ and B-B′ in FIG. 2 illustrating part of a flow for fabricating the semiconductor device in accordance with one embodiment of the present disclosure;

FIG. 5 illustrates, in a schematic top-view diagram, an intermediate semiconductor device in accordance with one embodiment of the present disclosure;

FIGS. 6 to 8 are schematic cross-sectional view diagrams taken along lines A-A′ and B-B′ in FIG. 5 illustrating part of the flow for fabricating the semiconductor device in accordance with one embodiment of the present disclosure;

FIG. 9 illustrates, in a schematic top-view diagram, an intermediate semiconductor device in accordance with one embodiment of the present disclosure;

FIGS. 10 and 11 are schematic cross-sectional view diagrams taken along lines A-A′ and B-B′ in FIG. 9 illustrating part of the flow for fabricating the semiconductor device in accordance with one embodiment of the present disclosure;

FIG. 12 illustrates, in a schematic top-view diagram, an intermediate semiconductor device in accordance with one embodiment of the present disclosure;

FIG. 13 is a schematic cross-sectional view diagram taken along lines A-A′ and B-B′ in FIG. 12;

FIG. 14 illustrates, in a schematic top-view diagram, an intermediate semiconductor device in accordance with one embodiment of the present disclosure;

FIGS. 15 and 16 are schematic cross-sectional view diagrams taken along lines A-A′ and B-B′ in FIG. 14 illustrating part of the flow for fabricating the semiconductor device in accordance with one embodiment of the present disclosure;

FIG. 17 illustrates, in a schematic top-view diagram, an intermediate semiconductor device in accordance with one embodiment of the present disclosure;

FIG. 18 is a schematic cross-sectional view diagram taken along lines A-A′ and B-B′ in FIG. 17;

FIG. 19 illustrates, in a schematic top-view diagram, an intermediate semiconductor device in accordance with one embodiment of the present disclosure;

FIG. 20 is a schematic cross-sectional view diagram taken along lines A-A′ and B-B′ in FIG. 19;

FIG. 21 illustrates, in a schematic top-view diagram, an intermediate semiconductor device in accordance with one embodiment of the present disclosure; and

FIGS. 22 to 29 are schematic cross-sectional view diagrams taken along lines A-A′ and B-B′ in FIG. 21 illustrating part of the flow for fabricating the semiconductor device in accordance with one embodiment of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

It should be understood that when an element or layer is referred to as being “connected to” or “coupled to” another element or layer, it can be directly connected to or coupled to another element or layer, or intervening elements or layers may be present.

It should be understood that, although the terms first, second, etc. may be used herein to describe various elements, these elements should not be limited by these terms. Unless indicated otherwise, these terms are only used to distinguish one element from another element. Thus, for example, a first element, a first component or a first section discussed below could be termed a second element, a second component or a second section without departing from the teachings of the present disclosure.

Unless the context indicates otherwise, terms such as “same,” “equal,” “planar,” or “coplanar,” as used herein when referring to orientation, layout, location, shapes, sizes, amounts, or other measures do not necessarily mean an exactly identical orientation, layout, location, shape, size, amount, or other measure, but are intended to encompass nearly identical orientation, layout, location, shapes, sizes, amounts, or other measures within acceptable variations that may occur, for example, due to manufacturing processes. The term “substantially” may be used herein to reflect this meaning. For example, items described as “substantially the same,” “substantially equal,” or “substantially planar,” may be exactly the same, equal, or planar, or may be the same, equal, or planar within acceptable variations that may occur, for example, due to manufacturing processes.

In the present disclosure, a semiconductor device generally means a device which can function by utilizing semiconductor characteristics, and an electro-optic device, a light-emitting display device, a semiconductor circuit, and an electronic device are all included in the category of the semiconductor device.

It should be noted that, in the description of the present disclosure, above (or up) corresponds to the direction of the arrow of the Z direction, and below (or down) corresponds to the opposite direction of the arrow of the Z direction.

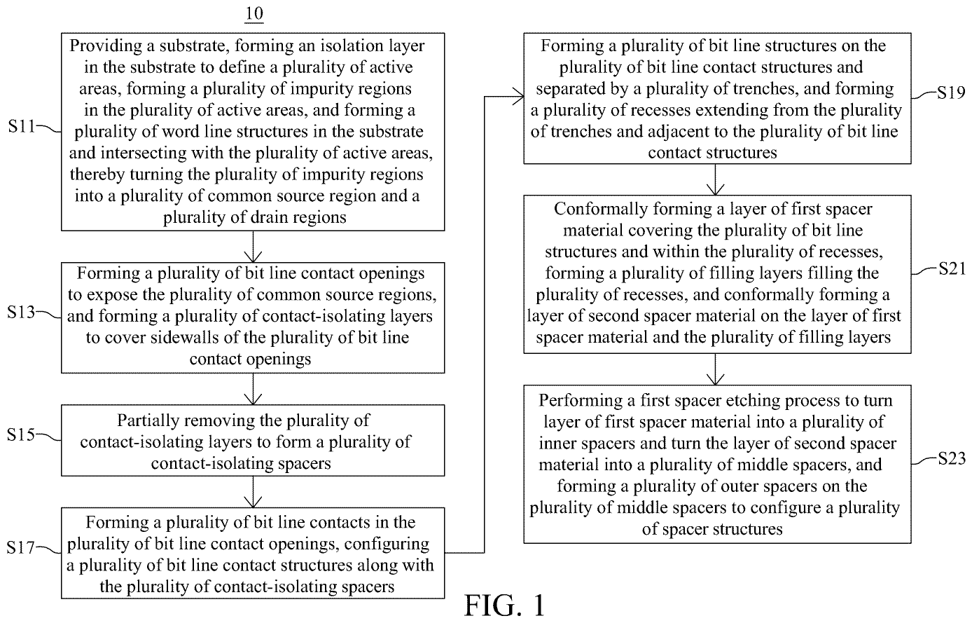

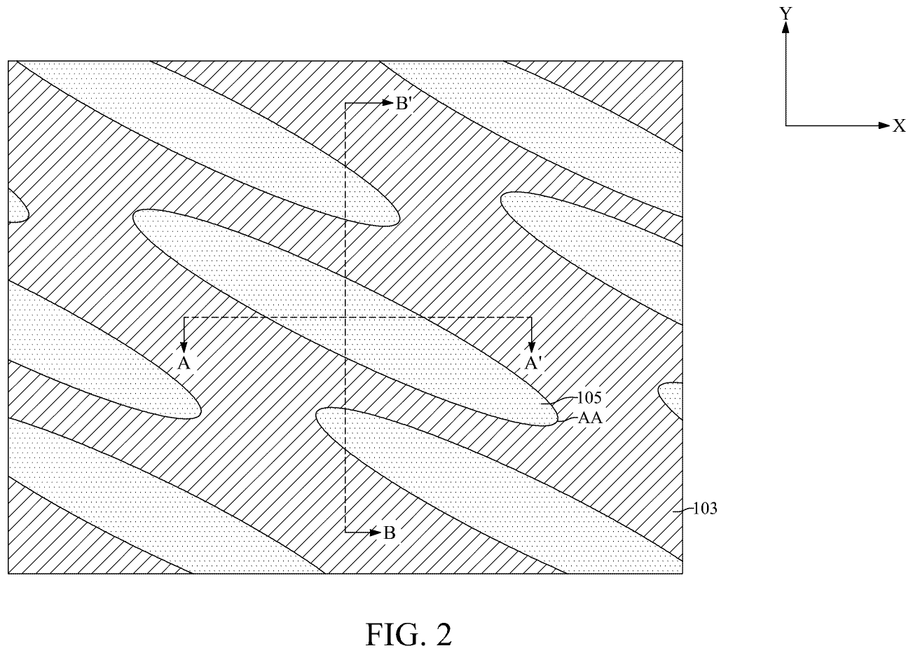

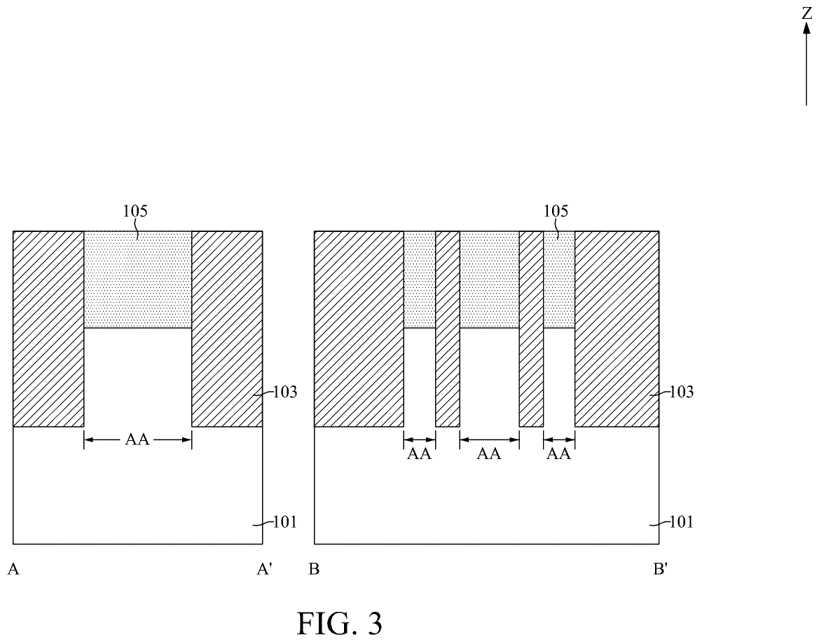

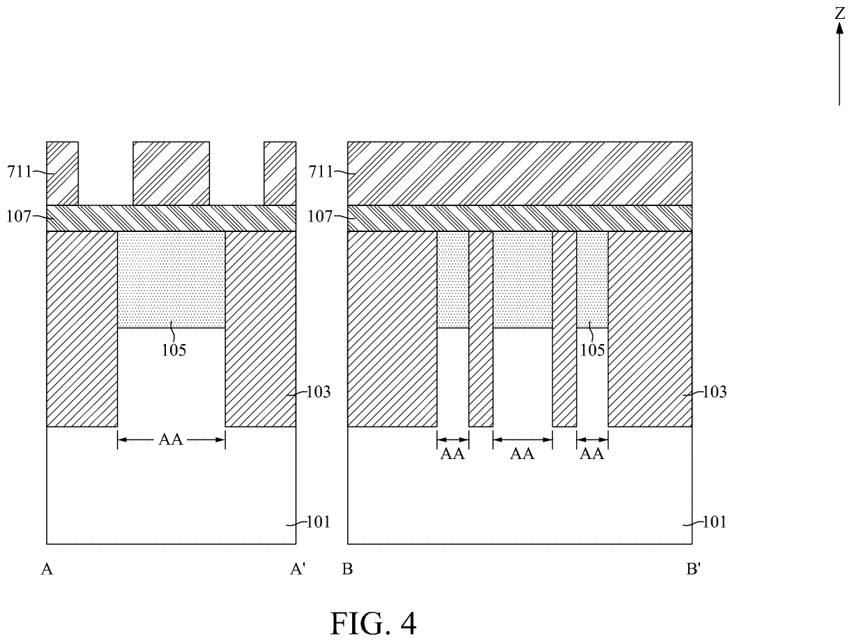

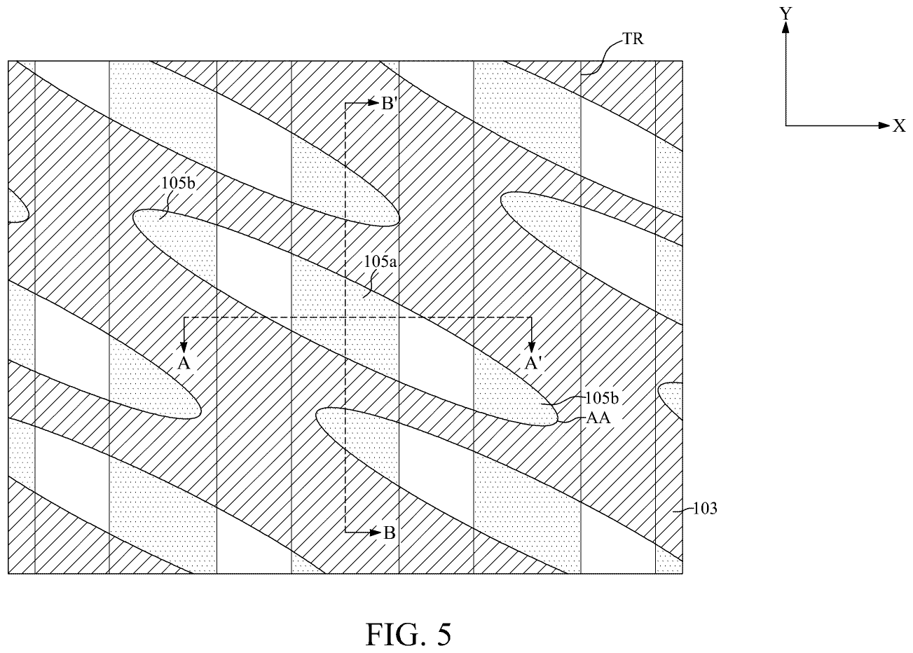

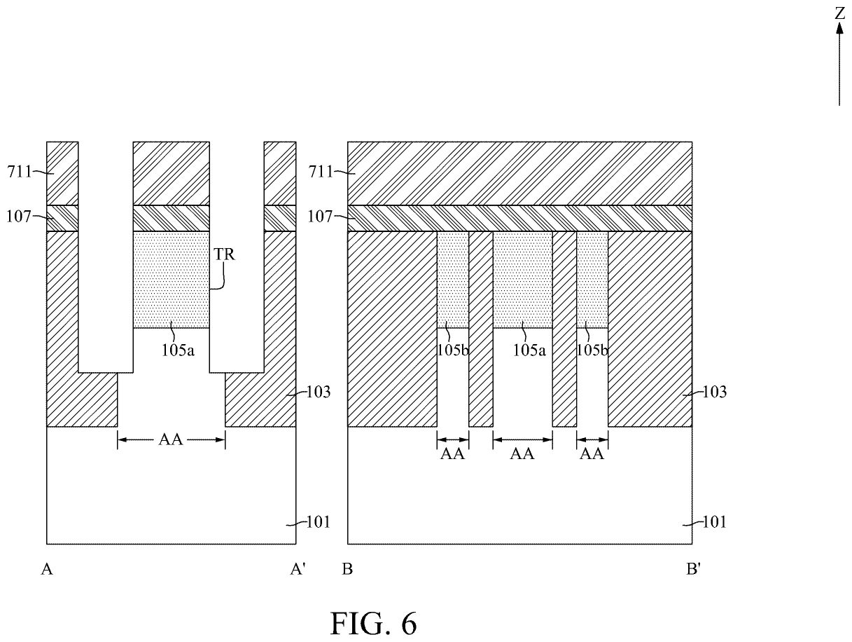

FIG. 1 illustrates, in a flowchart diagram form, a method 10 for fabricating a semiconductor device 1A in accordance with one embodiment of the present disclosure. FIG. 2 illustrates, in a schematic top-view diagram, an intermediate semiconductor device in accordance with one embodiment of the present disclosure. FIGS. 3 and 4 are schematic cross-sectional view diagrams taken along lines A-A′ and B-B′ in FIG. 2 illustrating part of a flow for fabricating the semiconductor device 1A in accordance with one embodiment of the present disclosure. FIG. 5 illustrates, in a schematic top-view diagram, an intermediate semiconductor device in accordance with one embodiment of the present disclosure. FIGS. 6 to 8 are schematic cross-sectional view diagrams taken along lines A-A′ and B-B′ in FIG. 5 illustrating part of the flow for fabricating the semiconductor device 1A in accordance with one embodiment of the present disclosure.

With reference to FIGS. 1 to 8, at step S11, a substrate 101 may be provided, an isolation layer 103 may be formed in the substrate 101 to define a plurality of active areas AA, a plurality of impurity regions 105 may be formed in the plurality of active areas AA, and a plurality of word line structures 510 may be formed in the substrate 101 and intersecting with the plurality of active areas AA, thereby turning the plurality of impurity regions 105 into a plurality of common source region 105a and a plurality of drain regions 105b.

With reference to FIGS. 2 and 3, the substrate 101 may include a bulk semiconductor substrate. The bulk semiconductor substrate may be formed of, for example, an elementary semiconductor, such as silicon or germanium; a compound semiconductor, such as silicon germanium, silicon carbide, gallium arsenide, gallium phosphide, indium phosphide, indium arsenide, indium antimonide, or other III-V compound semiconductor or II-VI compound semiconductor; or combinations thereof.

In some embodiments, the substrate 101 may include a semiconductor-on-insulator structure which consists of, from bottom to top, a handle substrate, an insulator layer, and a topmost semiconductor material layer. The handle substrate and the topmost semiconductor material layer may be formed of the same material as the bulk semiconductor substrate aforementioned. The insulator layer may be a crystalline or non-crystalline dielectric material such as an oxide and/or nitride. For example, the insulator layer may be a dielectric oxide such as silicon oxide. For another example, the insulator layer may be a dielectric nitride such as silicon nitride or boron nitride. For yet another example, the insulator layer may include a stack of a dielectric oxide and a dielectric nitride such as a stack of, in any order, silicon oxide and silicon nitride or boron nitride. The insulator layer may have a thickness between about 10 nm and about 200 nm. The insulator layer may eliminate leakage current between adjacent elements in the substrate 101 and reduce parasitic capacitance associated with source/drains.

It should be noted that, the term “about” modifying the quantity of an ingredient, component, or reactant of the present disclosure employed refers to variation in the numerical quantity that can occur, for example, through typical measuring and liquid handling procedures used for making concentrates or solutions. Furthermore, variation can occur from inadvertent error in measuring procedures, differences in the manufacture, source, or purity of the ingredients employed to make the compositions or carry out the methods, and the like. In one aspect, the term “about” means within 10% of the reported numerical value. In another aspect, the term “about” means within 5% of the reported numerical value. Yet, in another aspect, the term “about” means within 10, 9, 8, 7, 6, 5, 4, 3, 2, or 1% of the reported numerical value.

With reference to FIGS. 2 and 3, the isolation layer 103 may be formed in the substrate 101. A series of deposition processes may be performed to deposit a pad oxide layer (not shown) and a pad nitride layer (not shown) on the substrate 101. A photolithography process and a subsequent etching process, such as an anisotropic dry etching process, may be performed to form trenches penetrating through the pad oxide layer, the pad nitride layer, and extending to the substrate 101. An insulating material may be deposited into the trenches and a planarization process, such as chemical mechanical polishing, may be subsequently performed until the top surface of the substrate 101 is exposed to remove excess filling material, provide a substantially flat surface for subsequent processing steps, and concurrently form the isolation layer 103. The insulating material may be, for example, silicon oxide or other applicable insulating materials. The isolation layer 103 may define the plurality of active areas AA in the substrate 101.

It should be noted that, in the description of the present disclosure, a surface of an element (or a feature) located at the highest vertical level along the Z axis is referred to as a top surface of the element (or the feature). A surface of an element (or a feature) located at the lowest vertical level along the Z axis is referred to as a bottom surface of the element (or the feature).

It should be noted that each of the plurality of active areas AA may comprise a portion of the substrate 101 and a space above the portion of the substrate 101. Describing an element as being disposed on the active area AA means that the element is disposed on a top surface of the portion of the substrate 101. Describing an element as being disposed in the active area AA means that the element is disposed in the portion of the substrate 101; however, a top surface of the element may be even with the top surface of the portion of the substrate 101. Describing an element as being disposed above the active area AA means that the element is disposed above the top surface of the portion of the substrate 101.

With reference to FIGS. 2 and 3, a plurality of impurity regions 105 may be formed in the plurality of active areas AA, respectively and correspondingly. In some embodiments, the plurality of impurity regions 105 may be formed by an implantation process. That is, the plurality of impurity regions 105 may be turned from portions of the plurality of active areas AA. The dopants of the implantation process may include p-type impurities (dopants) or n-type impurities (dopants). The p-type impurities may be added to an intrinsic semiconductor to create deficiencies of valence electrons. In a silicon-containing substrate, examples of p-type dopants, i.e., impurities include but are not limited to boron, aluminum, gallium, and indium. The n-type impurities may be added to an intrinsic semiconductor to contribute free electrons to the intrinsic semiconductor. In a silicon-containing substrate, examples of n-type dopants, i.e., impurities, include but are not limited to antimony, arsenic, and phosphorus. In some embodiments, the dopant concentration of the plurality of impurity regions 105 may be between about 1E19 atoms/cm\hat{ }3 and about 1E21 atoms/cm\hat{ }3. After the implantation process, the plurality of impurity regions 105 may have an electrical type such as n-type or p-type.

With reference to FIG. 4, a bottom insulating layer 107 may be formed on the substrate 101 and the isolation layer 103. In some embodiments, the bottom insulating layer 107 may be formed of a material having etching selectivity to the substrate 101 and the isolation layer 103. In some embodiments, the bottom insulating layer 107 may be formed of, for example, silicon nitride, boron nitride, silicon boron nitride, phosphorus boron nitride, boron carbon silicon nitride, or a combination thereof. In some embodiments, the bottom insulating layer 107 may be formed of, for example, silicon nitride. In some embodiments, the bottom insulating layer 107 may be formed by, for example, chemical vapor deposition, plasma-enhanced chemical vapor deposition, or other applicable deposition processes.

With reference to FIG. 4, a first mask layer 711 may be formed on the bottom insulating layer 107. In some embodiments, the first mask layer 711 may be a photoresist layer and may include a pattern of the plurality of word line structures 510.

It should be noted that the bottom insulating layer 107 is not shown in FIG. 5 for clarity.

With reference to FIGS. 5 and 6, an etching process using the first mask layer 711 as the mask may be performed to form a plurality of word line trenches TR in the substrate 101. In some embodiments, the plurality of word line trenches TR may have a line-shaped cross-sectional profile, extend along the direction Y, and travers (or intersect) with the plurality of impurity regions 105 in a top-view perspective. For example, each impurity region 105 may be intersected with two word line trenches TR. The plurality of word line trenches TR may divide each of the plurality of impurity regions 105 into a plurality of common source regions 105a and a plurality of drain regions 105b. For one impurity region 105, one common source region 105a may be formed between the two word line trenches TR and two drain regions 105b may be respectively and correspondingly formed between the isolation layer 103 and the two word line trenches TR.

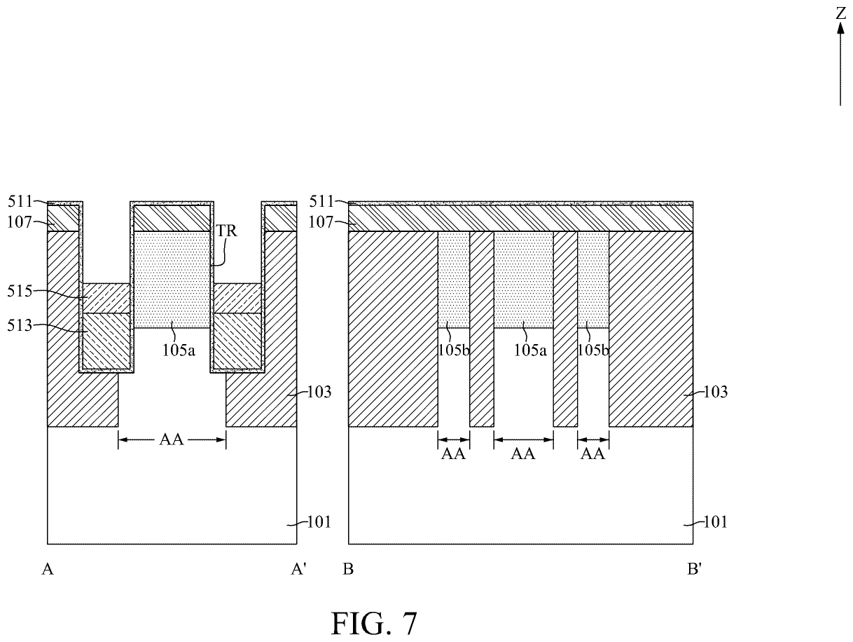

With reference to FIG. 7, a word line dielectric layer 511 may be conformally formed on the inner surface of the word line trench TR and on the top surface of the bottom insulating layer 107. The word line dielectric layer 511 may have a U-shaped cross-sectional profile within the word line trench TR. In some embodiments, the word line dielectric layer 511 may be formed by a thermal oxidation process. For example, the word line dielectric layer 511 may be formed by oxidizing the inner surface of the word line trench TR. In some embodiments, the word line dielectric layer 511 may be formed by a deposition process such as a chemical vapor deposition or an atomic layer deposition. The word line dielectric layer 511 may include a high-k material, an oxide, a nitride, an oxynitride or combinations thereof. In some embodiments, after a liner polysilicon layer (not shown for clarity) is deposited, the word line dielectric layer 511 may be formed by radical oxidizing the liner polysilicon layer. In some embodiments, after a liner silicon nitride layer (not shown for clarity) is formed, the word line dielectric layer 511 may be formed by radical oxidizing the liner silicon nitride layer.

In some embodiments, the high-k material may include a hafnium-containing material. The hafnium-containing material may be, for example, hafnium oxide, hafnium silicon oxide, hafnium silicon oxynitride, or a combination thereof. In some embodiments, the high-k material may be, for example, lanthanum oxide, lanthanum aluminum oxide, zirconium oxide, zirconium silicon oxide, zirconium silicon oxynitride, aluminum oxide or a combination thereof.

With reference to FIG. 7, a plurality of word line bottom conductive layers 513 may be formed on the word line dielectric layer 511 and within the plurality of word line trenches TR, respectively and correspondingly. In some embodiments, in order to form the plurality of word line bottom conductive layers 513, a conductive layer (not shown for clarity) may be formed to fill the plurality of word line trenches TR, and a recessing process may be subsequently performed. The recessing process may be performed as an etching back process or sequentially performed as the planarization process and an etching back process. The plurality of word line bottom conductive layers 513 may have a recessed shape that partially fills the plurality of word line trenches TR. That is, the top surface of the plurality of word line bottom conductive layers 513 may be lower than the top surface of the substrate 101.

In some embodiments, the plurality of word line bottom conductive layers 513 may include a metal, a metal nitride, or a combination thereof. For example, the plurality of word line bottom conductive layers 513 may be formed of titanium nitride, tungsten, or a titanium nitride/tungsten. After the titanium nitride is conformally formed, the titanium nitride/tungsten may have structures where the plurality of word line trenches TR are partially filled using tungsten. The titanium nitride or the tungsten may be solely used for the plurality of word line bottom conductive layers 513. In some embodiments, the plurality of word line bottom conductive layers 513 may be formed of, for example, a conductive material such as doped polycrystalline silicon, doped polycrystalline silicon germanium, or a combination thereof. In some embodiments, the plurality of word line bottom conductive layers 513 may be formed of, for example, tungsten, aluminum, titanium, copper, the like, or a combination thereof.

With reference to FIG. 7, a plurality of word line top conductive layers 515 may be formed on the plurality of word line bottom conductive layers 513 and within the plurality of word line trenches TR, respectively and correspondingly. In some embodiments, in order to form the plurality of word line top conductive layers 515, a conductive layer (not shown for clarity) may be formed to fill the plurality of word line trenches TR, and a recessing process may be subsequently performed. The recessing process may be performed as an etching back process or sequentially performed as the planarization process and an etching back process. The plurality of word line top conductive layers 515 may have a recessed shape that partially fills the plurality of word line trenches TR. That is, the top surface of the plurality of word line bottom conductive layers 513 may be lower than the top surface of the substrate 101.

In some embodiments, the plurality of word line top conductive layers 515 may include for example, polycrystalline silicon, polycrystalline germanium, polycrystalline silicon germanium, doped polycrystalline silicon, doped polycrystalline germanium, doped polycrystalline silicon germanium, or a combination thereof. In some embodiments, the plurality of word line top conductive layers 515 may be doped with p-type dopants or n-type dopants. In some embodiments, doping may be performed by incorporating the dopants during the deposition process for forming the conductive layer.

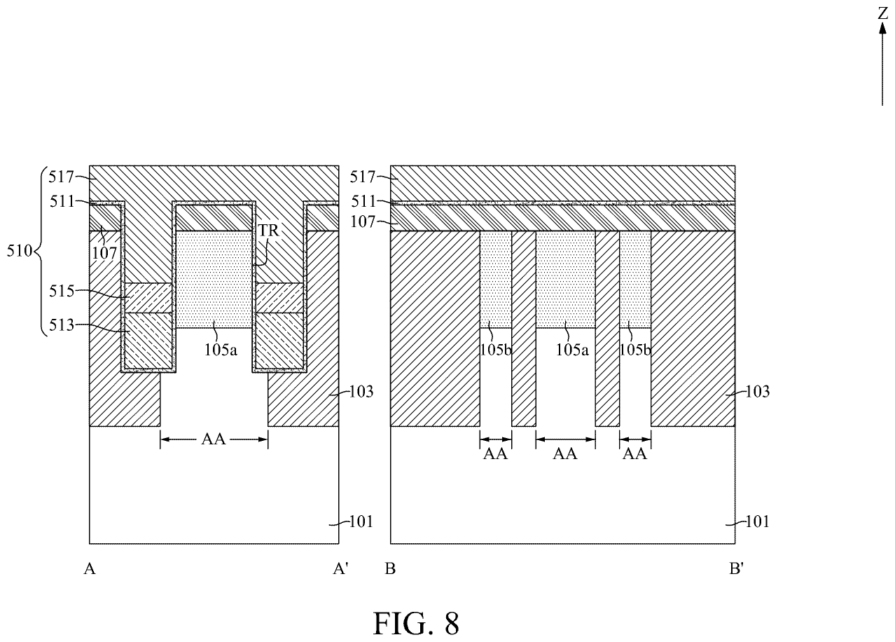

With reference to FIG. 8, a dielectric material may be deposited by, for example, chemical vapor deposition, to completely fill the plurality of word line trenches TR and covering the top surface of the bottom insulating layer 107. A planarization process, such as chemical mechanical polishing, may be performed to provide a substantially flat surface for subsequent processing steps and form a word line capping layer 517. In some embodiments, the word line capping layer 517 may include, for example, silicon nitride, or other applicable dielectric material. The word line dielectric layer 511, the plurality of word line bottom conductive layers 513, the plurality of word line top conductive layers 515, and the word line capping layer 517 together configure the plurality of word line structures 510. The plurality of word line structures 510 may separate the plurality of common source regions 105a from the plurality of drain regions 105b, respectively and correspondingly.

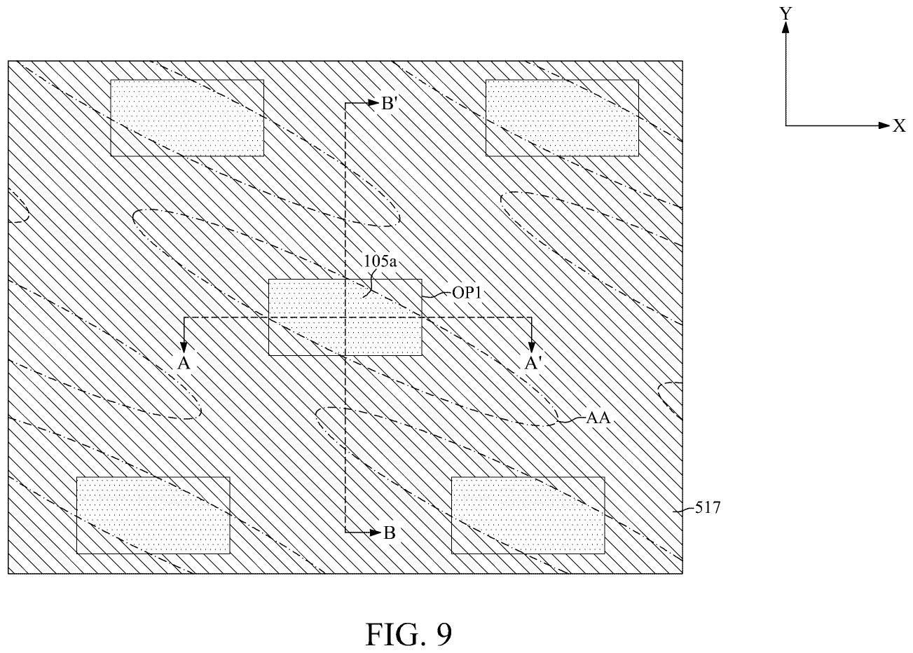

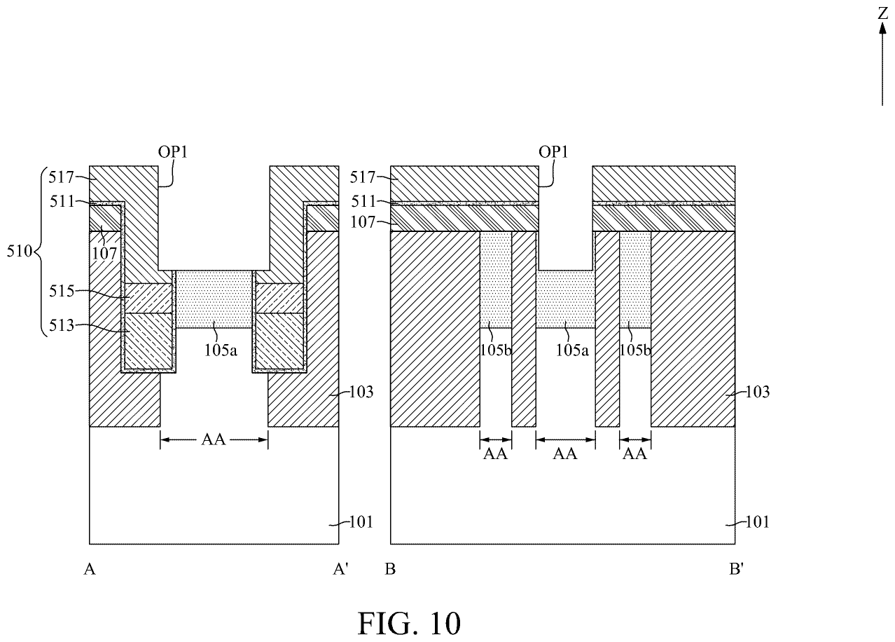

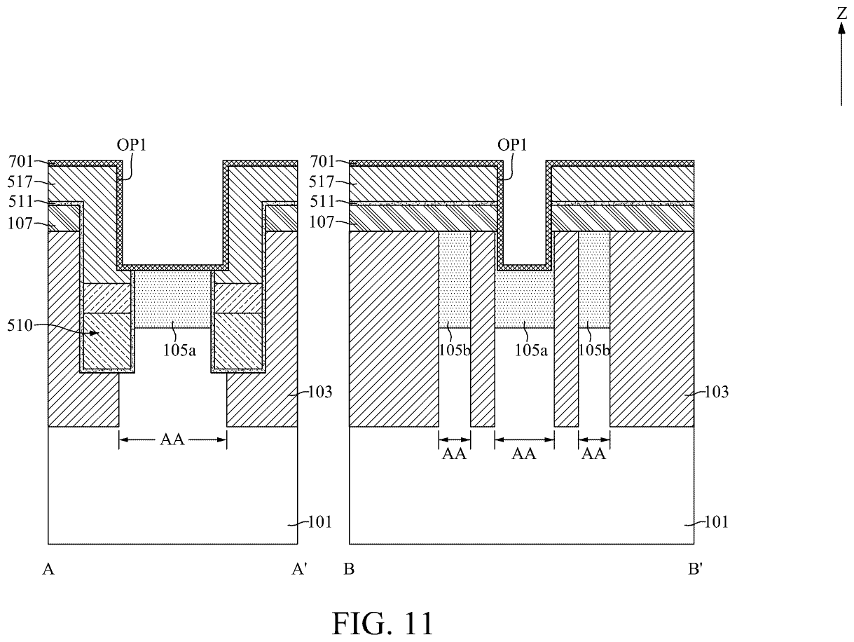

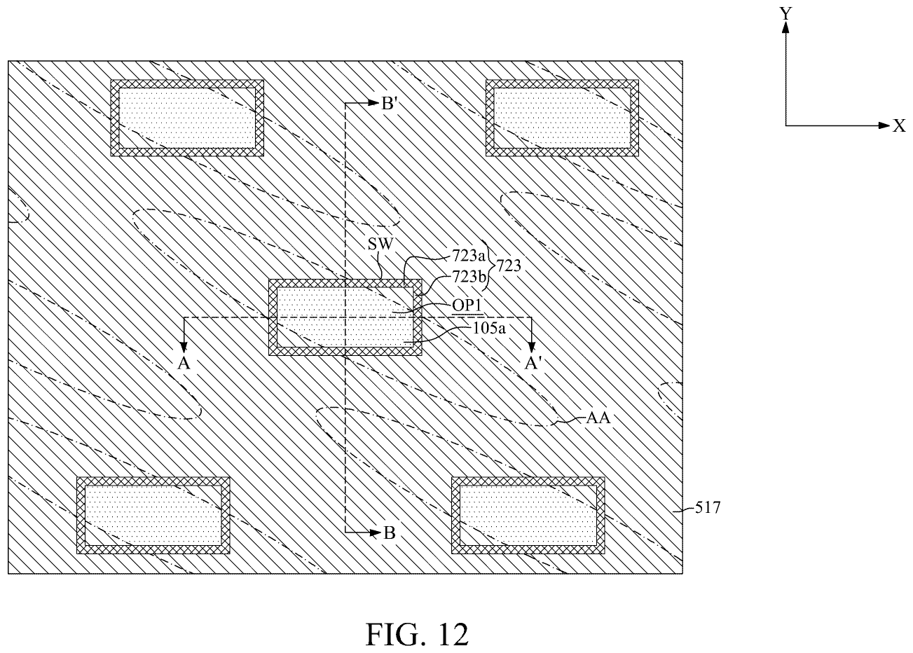

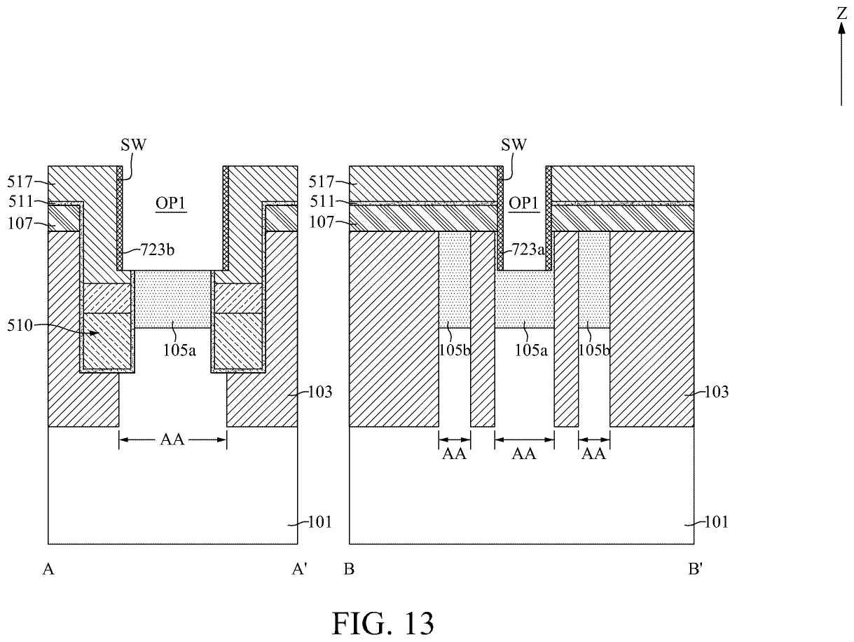

FIG. 9 illustrates, in a schematic top-view diagram, an intermediate semiconductor device in accordance with one embodiment of the present disclosure. FIGS. 10 and 11 are schematic cross-sectional view diagrams taken along lines A-A′ and B-B′ in FIG. 9 illustrating part of the flow for fabricating the semiconductor device 1A in accordance with one embodiment of the present disclosure. FIG. 12 illustrates, in a schematic top-view diagram, an intermediate semiconductor device in accordance with one embodiment of the present disclosure. FIG. 13 is a schematic cross-sectional view diagram taken along lines A-A′ and B-B′ in FIG. 12.

With reference to FIG. 1 and FIGS. 9 to 13, at Step S13, a plurality of bit line contact openings OP1 may be formed to expose the plurality of common source regions 105a, and a plurality of contact-isolating layers 723 may be formed to cover sidewalls SW of the plurality of bit line contact openings OP1.

With reference to FIGS. 9 and 10, the plurality of bit line contact openings OP1 may be formed by a photolithography process and a subsequent etching process. The bit line contact opening OP1 may penetrate the word line capping layer 517, the word line dielectric layer 511, and the bottom insulating layer 107 and extend to the substrate 101. The common source region 105a may be exposed through the bit line contact opening OP1. In some embodiments, the bit line contact opening OP1 may have a rectangular or square cross-sectional profile in a top-view perspective.

With reference to FIG. 11, a layer of first insulating material 701 may be conformally formed within the plurality of bit line contact openings OP1 and on the top surface of the word line capping layer 517. In some embodiments, the first insulating material 701 may include, for example, a material having etching selectivity to the substrate 101. In some embodiments, the first insulating material 701 may include, for example, silicon nitride or other applicable insulating materials. In some embodiments, the layer of first insulating material 701 may be formed by, for example, atomic layer deposition, chemical vapor deposition, or other applicable deposition processes.

With reference to FIGS. 12 and 13, an etching process may be performed to remove the first insulating material 701 formed on the common source region 105a. In some embodiments, the etching process may be an anisotropic etching process. For example, the etching process may be an anisotropic dry etching process. After the etching process, the remaining first insulating material 701 on the sidewalls SW of the plurality of bit line contact openings OP1 may be referred to as the plurality of contact-isolating layers 723.

With reference to FIGS. 12 and 13, each of the plurality of contact-isolating layers 723 may include two first portions 723a and two second portions 723b. In a top-view perspective, the two first portions 723a may be parallel to each other and extend along the direction X. The two second portions 723b may be parallel to each other and extend along the direction Y. The first portions 723a and the second portions 723b together configure a rectangular ring or square-ring cross sectional profile in a top-view perspective.

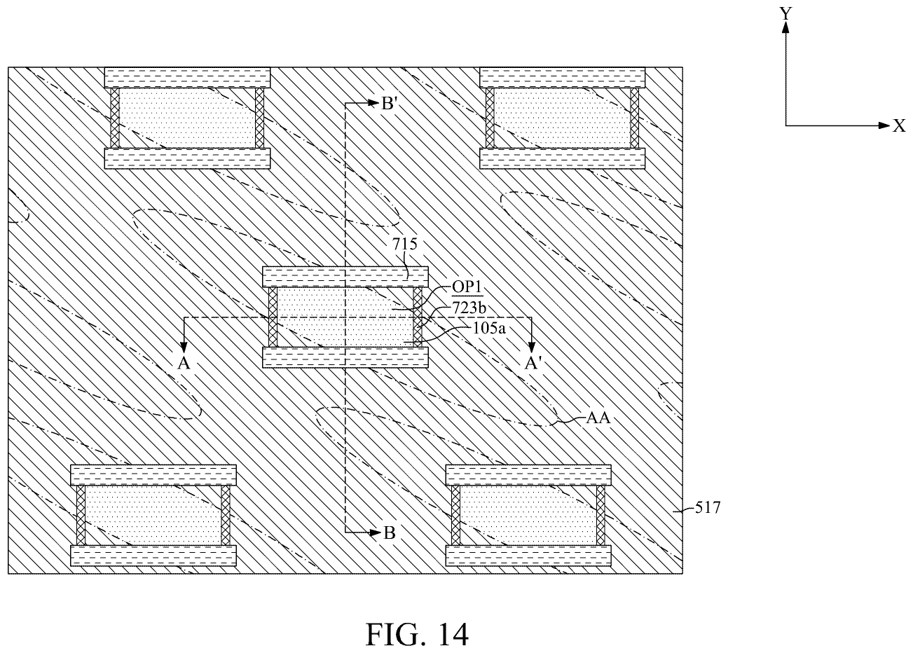

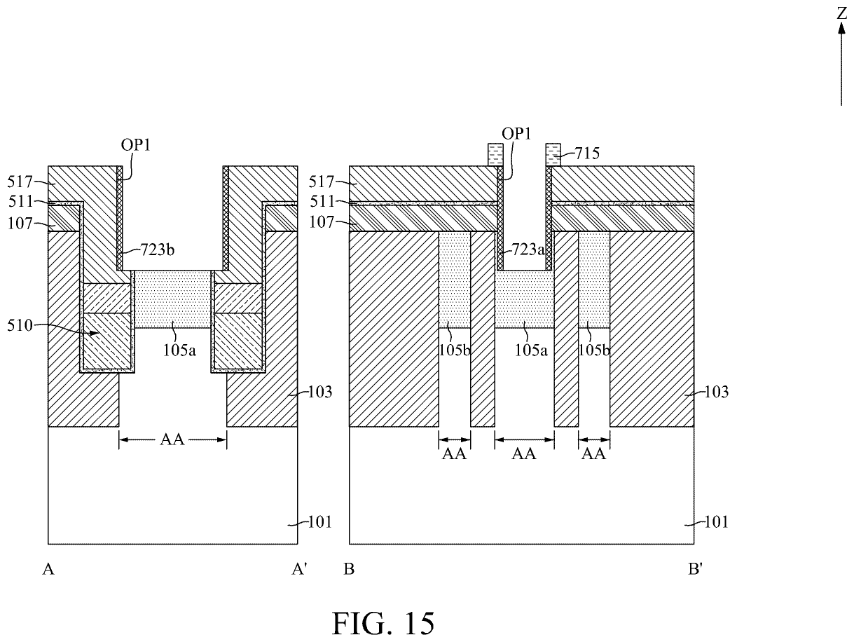

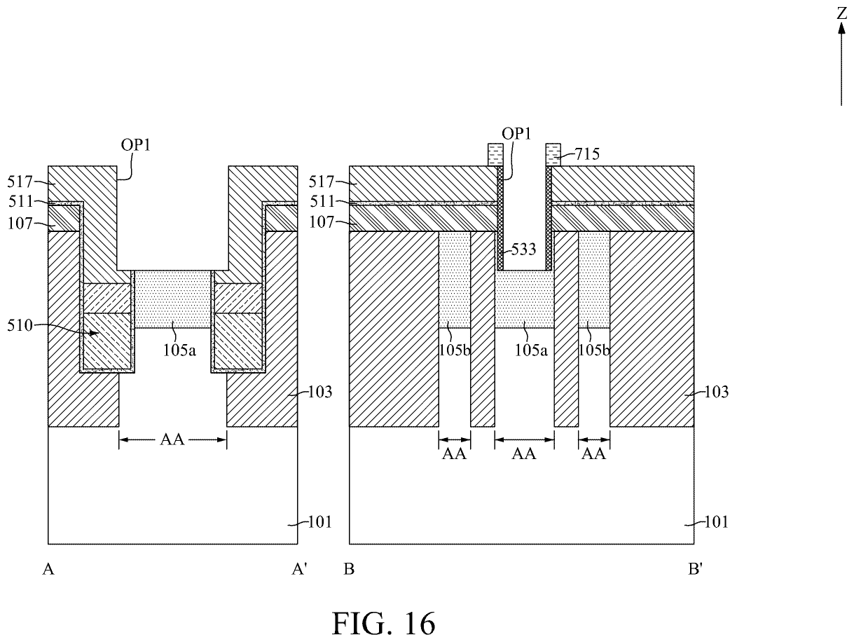

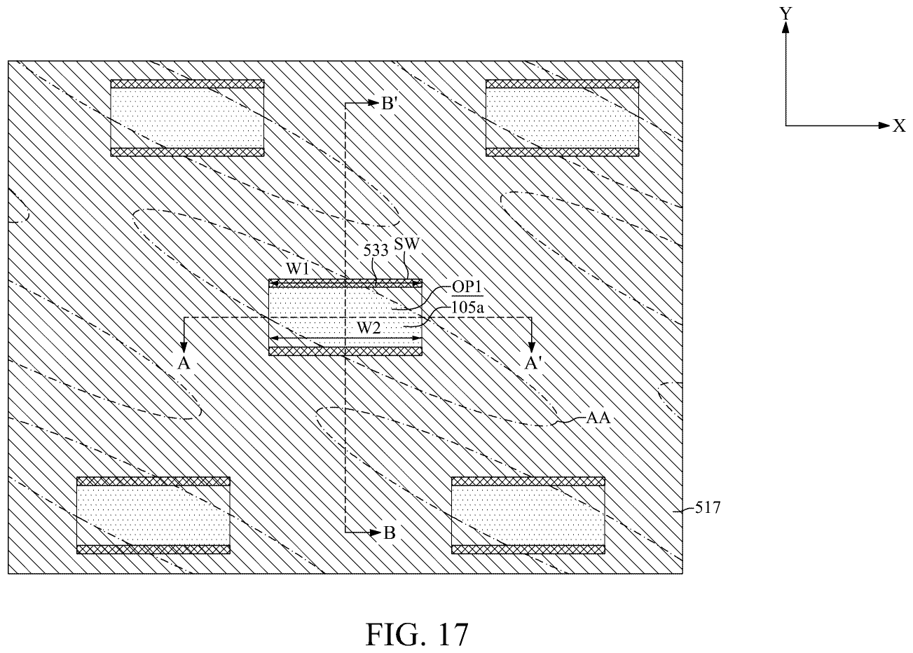

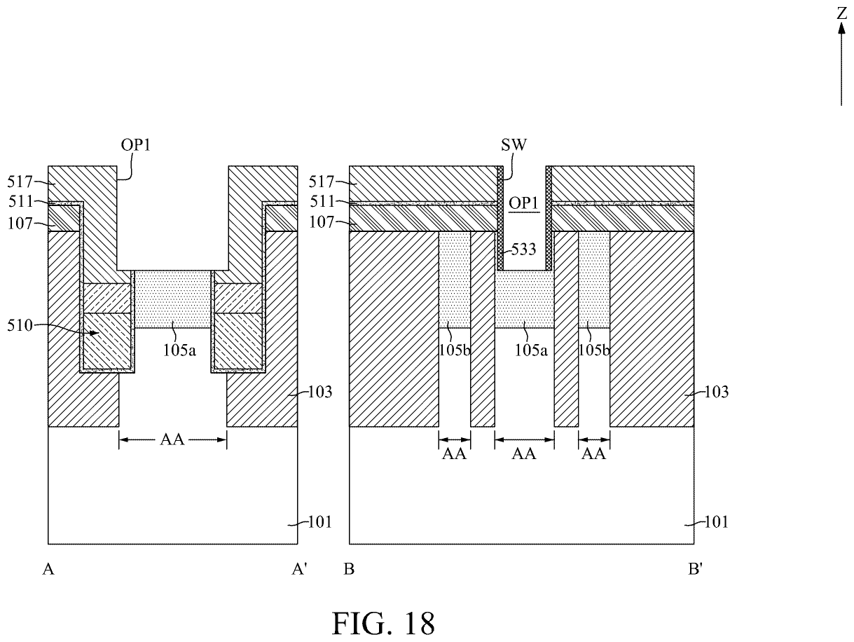

FIG. 14 illustrates, in a schematic top-view diagram, an intermediate semiconductor device in accordance with one embodiment of the present disclosure. FIGS. 15 and 16 are schematic cross-sectional view diagrams taken along lines A-A′ and B-B′ in FIG. 14 illustrating part of the flow for fabricating the semiconductor device 1A in accordance with one embodiment of the present disclosure. FIG. 17 illustrates, in a schematic top-view diagram, an intermediate semiconductor device in accordance with one embodiment of the present disclosure. FIG. 18 is a schematic cross-sectional view diagram taken along lines A-A′ and B-B′ in FIG. 17.

With reference to FIG. 1 and FIGS. 14 to 18, at step S15, the plurality of contact-isolating layers 723 may be partially removed to form a plurality of contact-isolating spacers 533.

With reference to FIGS. 14 and 15, a plurality of hard mask layers 715 may be formed on the word line capping layer 517 to selectively mask the first portions 723a. In some embodiments, the plurality of hard mask layers 715 may include a material having etching selectivity to the word line capping layer 517 and the substrate 101. In some embodiments, the plurality of hard mask layers 715 may be formed of, for example, boron nitride, silicon boron nitride, phosphorus boron nitride, boron carbon silicon nitride, or the like. In some alternative embodiments, the plurality of hard mask layers 715 may be photoresist layers.

With reference to FIG. 16, an etching process may be performed using the plurality of hard mask layers 715 as the mask to selectively remove the second portions 723b. In some embodiments, the etching process may be an anisotropic etching process such as an anisotropic dry etching process. The remaining first portions 723a may be referred to as the contact-isolating spacers 533.

With reference to FIGS. 17 and 18, the plurality of hard mask layers 715 may be removed. For each of the bit line contact opening OP1, two contact-isolating spacers 533 may be disposed on the sidewall SW of the bit line contact opening OP1, parallel to each other, and extending along the direction X in a top-view perspective. In some embodiments, the width W1 of the contact-isolating spacer 533 and the width W2 of the bit line contact opening OP1 may be substantially the same. In some embodiments, the W1 of the contact-isolating spacer 533 may be less than the width W2 of the bit line contact opening OP1. In some embodiments, the ratio of the W1 of the contact-isolating spacer 533 to the width W2 of the bit line contact opening OP1 may be between about 0.90 and 1.00 or between about 0.95 and 1.00.

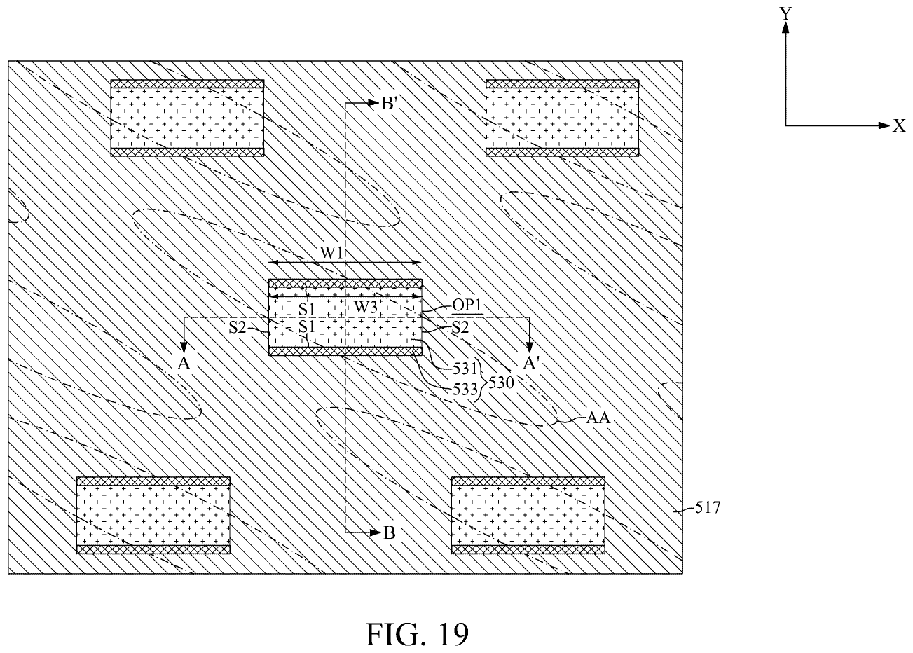

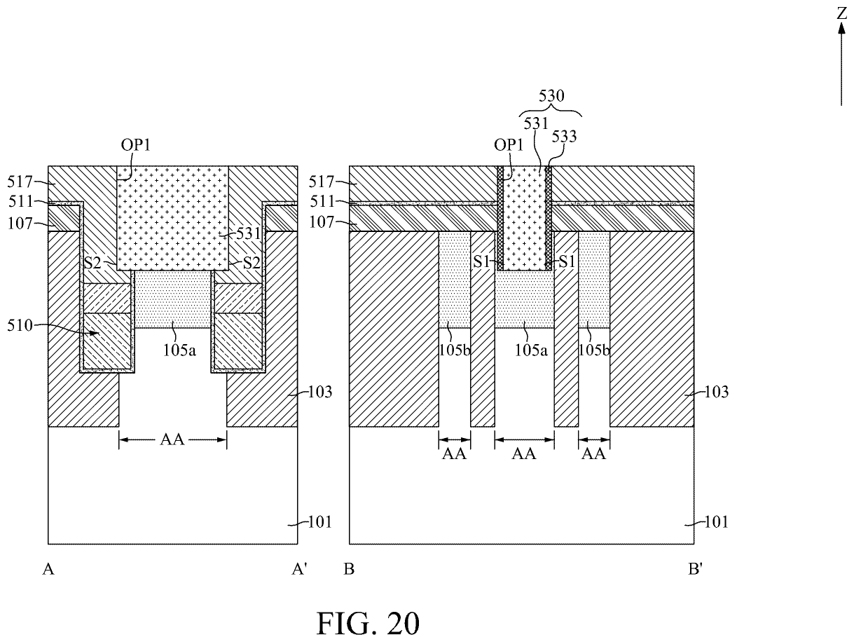

FIG. 19 illustrates, in a schematic top-view diagram, an intermediate semiconductor device in accordance with one embodiment of the present disclosure. FIG. 20 is a schematic cross-sectional view diagram taken along lines A-A′ and B-B′ in FIG. 19.

With reference to FIG. 1 and FIGS. 19 and 20, at step S17, a plurality of bit line contacts 531 may be formed in the plurality of bit line contact openings OP1, configuring a plurality of bit line contact structures 530 along with the plurality of contact-isolating spacers 533.

With reference to FIGS. 19 and 20, a conductive material (not shown) may be formed to completely fill the plurality of bit line contact openings OP1. A planarization process, such as chemical mechanical polishing, may be performed until the top surface of the word line capping layer 517 is exposed to remove excess material, provide a substantially flat surface for subsequent processing steps, and concurrently form the plurality of bit line contacts 531. In some embodiments, the conductive material may be, for example, tungsten, cobalt, zirconium, tantalum, titanium, aluminum, ruthenium, copper, metal carbides (e.g., tantalum carbide, titanium carbide, tantalum magnesium carbide), metal nitrides (e.g., titanium nitride), transition metal aluminides, or a combination thereof. In some embodiments, the conductive material may be formed by, for example, physical vapor deposition, chemical vapor deposition, or other applicable deposition processes.

In some embodiments, the plurality of bit line contacts 531 may have a square-shaped or rectangular cross-sectional profile in a top-view perspective. In some embodiments, each of the plurality of bit line contacts 531 may include two first sides S1 and two second sides S2. The two first sides S1 may be parallel to each other and extending along the direction X. The two second sides S2 may be parallel to each other and extending along the direction Y. The two contact-isolating spacers 533 may cover the two first sides S1, respectively and correspondingly. In some embodiments, the width W3 (distance between the two second sides S2) of the bit line contact 531 and the width W1 of the contact-isolating spacers 533 may be substantially the same. In some embodiments, the width W3 of the bit line contact 531 may be greater than the width W1 of the contact-isolating spacers 533. In some embodiments, the ratio of the W1 of the contact-isolating spacer 533 to the width W3 of the bit line contact 531 may be between about 0.90 and 1.00 or between about 0.95 and 1.00.

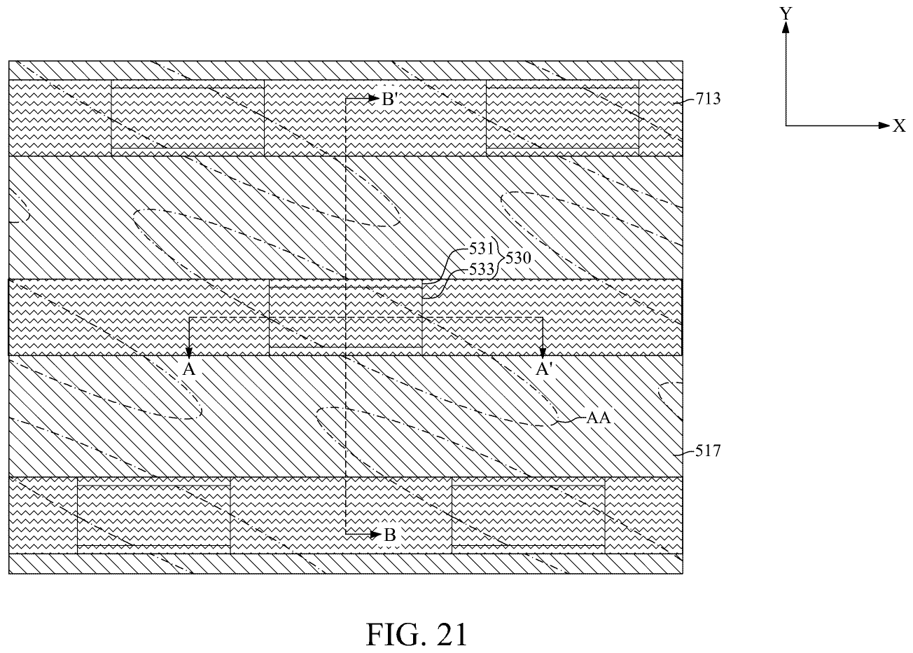

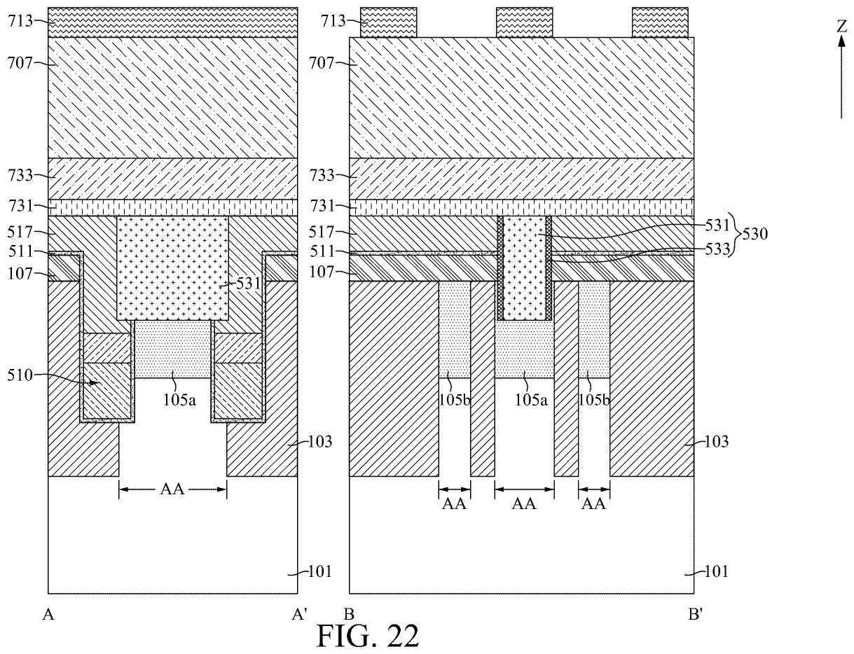

FIG. 21 illustrates, in a schematic top-view diagram, an intermediate semiconductor device in accordance with one embodiment of the present disclosure. FIGS. 22 to 29 are schematic cross-sectional view diagrams taken along lines A-A′ and B-B′ in FIG. 21 illustrating part of the flow for fabricating the semiconductor device 1A in accordance with one embodiment of the present disclosure.

With reference to FIG. 1 and FIGS. 21 to 23, at step S19, a plurality of bit line structures 520 may be formed on the plurality of bit line contact structures 530 and separated by a plurality of trenches TR1, and a plurality of recesses R1 may be formed extending from the plurality of trenches TR1 and adjacent to the plurality of bit line contact structures 530.

With reference to FIGS. 21 and 22, a layer of first conductive material 731 may be formed on the word line capping layer 517 and the plurality of bit line contact structures 530. In some embodiments, the first conductive material 731 may include, for example, doped polycrystalline silicon, doped polycrystalline germanium, doped polycrystalline silicon germanium, or a combination thereof. In some embodiments, the dopants for the layer of first conductive material 731 may include boron, aluminum, gallium, indium, antimony, arsenic, or phosphorus. In some embodiments, the layer of first conductive material 731 may be formed by, for example, chemical vapor deposition or other applicable deposition processes.

With reference to FIGS. 21 and 22, a layer of second conductive material 733 may be formed on the layer of first conductive material 731. In some embodiments, the second conductive material 733 may include, for example, titanium, nickel, platinum, tantalum, cobalt, silver, copper, aluminum, other applicable conductive material, or a combination thereof. In some embodiments, the layer of second conductive material 733 may be formed by, for example, physical vapor deposition, chemical vapor deposition, or other applicable deposition processes.

With reference to FIGS. 21 and 22, a layer of second insulating material 707 may be formed on the layer of second conductive material 733. In some embodiments, the second insulating material 707 may include, for example, silicon nitride or other applicable insulating material. In some embodiments, the layer of second insulating material 707 may be formed by, for example, chemical vapor deposition or other applicable deposition processes.

With reference to FIGS. 21 and 22, a second mask layer 713 may be formed on the layer of second insulating material 707. In some embodiments, the second mask layer 713 may be a photoresist layer and may include the pattern of the plurality of bit line structures 520. In some embodiments, in a top-view perspective, the pattern of the second mask layer 713 may include multiple line-shaped cross-sectional profiles extending along the direction X and alternatively arranged along the direction Y.

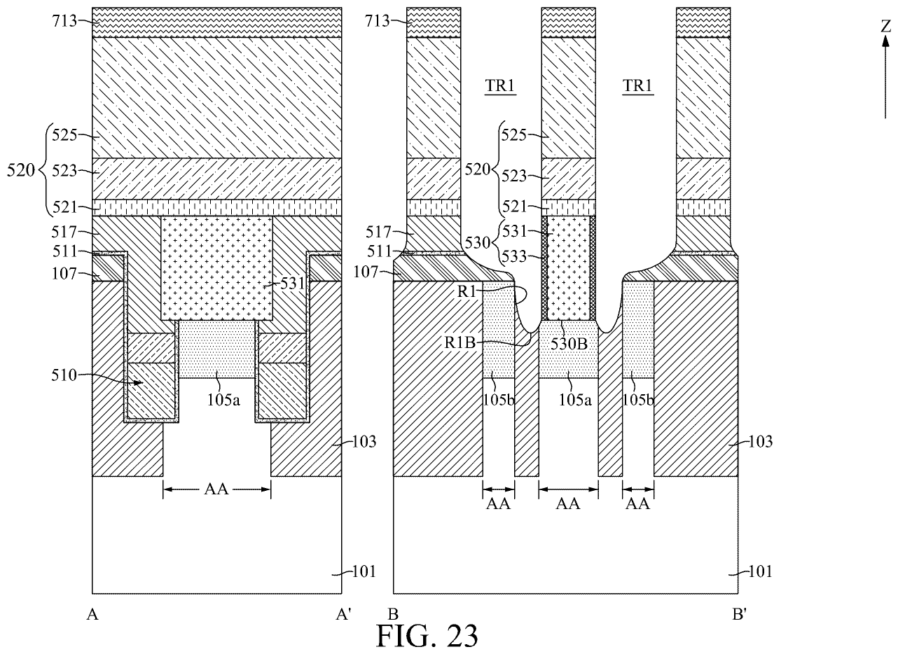

With reference to FIG. 23, an etching process may be performed using the second mask layer 713 as the mask to remove portions of the second insulating material 707, the second conductive material 733, and the first conductive material 731. In some embodiments, the etching process may be an anisotropic etching process such as an anisotropic dry etching process. After the etching process, the remaining first conductive material 731 may be referred to as a plurality of bit line bottom conductive layers 521. The remaining second conductive material 733 may be referred to as a plurality of bit line top conductive layers 523. The remaining second insulating material 707 may be referred to as a plurality of bit line capping layers 525. The plurality of bit line bottom conductive layers 521, the plurality of bit line top conductive layers 523, and the plurality of bit line capping layers 525 together configure the plurality of bit line structures 520.

The spaces between the plurality of bit line structures 520 may be referred to as the plurality of trenches TR1. The plurality of trenches TR1 may extend along the direction X. The plurality of recesses R1 may be formed extending from the plurality of trenches TR1 and disposed adjacent to the plurality of bit line contact structures 530. The contact-isolating spacers 533 may be exposed through the plurality of recesses R1. In some embodiments, the bottoms R1B of the plurality of recesses R1 may be lower than the bottom surface 530B of the bit line contact structure 530.

After the formation of the plurality of bit line structures 520, the second mask layer 713 may be removed by ashing or other applicable processes.

With reference to FIG. 1 and FIGS. 24 to 26, at step S21, a layer of first spacer material 741 may be conformally formed covering the plurality of bit line structures 520 and within the plurality of recesses R1, a plurality of filling layers 310 may be formed filling the plurality of recesses R1, and a layer of second spacer material 743 may be conformally formed on the layer of first spacer material 741 and the plurality of filling layers 310.

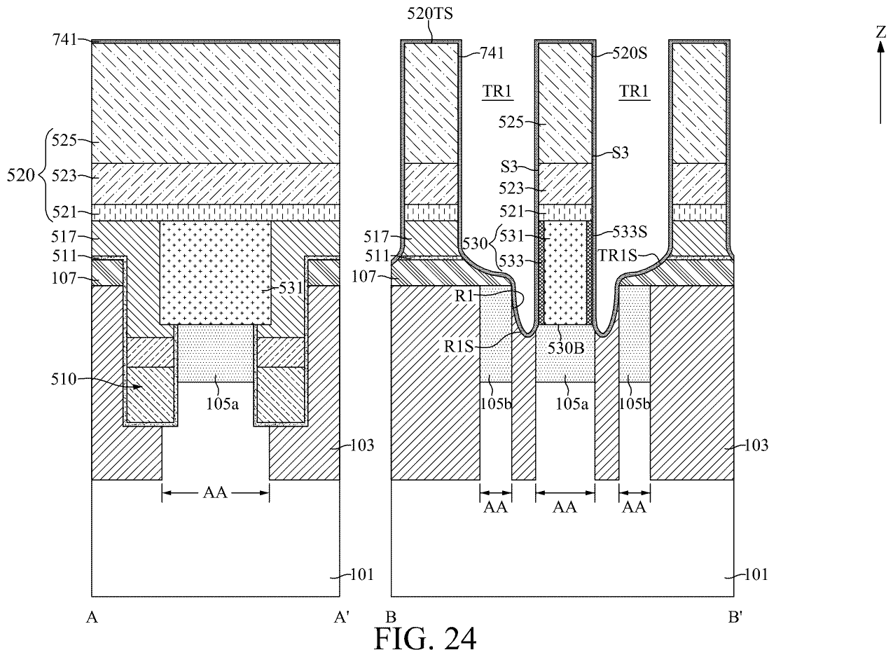

With reference to FIG. 24, the layer of first spacer material 741 may be conformally formed on the plurality of bit line structures 520 and the surfaces TR1S of the plurality of trenches TR1 and the surfaces R1S of the plurality of recesses R1. That is, the top surfaces 520TS, sidewalls S3 of the plurality of bit line structures 520 and the sidewalls 533S of the contact-isolating spacers 533 may be covered by the layer of first spacer material 741.

In some embodiments, the first spacer material 741 may be, for example, silicon oxycarbide. The formula of the silicon oxycarbide films is generally referred to as SiCO. This notation does not limit the bonding or chemical state of Si, O, or C. In some embodiments, the first spacer material 741 may include elements in addition to Si, O, and/or C, such as S. In some embodiments, the layer of first spacer material 741 may include Si—C bonds and/or Si—O bonds. In some embodiments, the layer of first spacer material 741 may include both Si—C and Si—O bonds and may not include Si—N bonds. Si—S bonds may also be present in addition to Si—C and/or Si—O bonds. In some embodiments, In some cases, the layer of first spacer material 741 may have more Si—O bonds than Si—C bonds, with a ratio ranging from about 1:1 to about 10:1.

In some embodiments, the carbon content of the first spacer material 741 on an atomic basis may range from about 0.1% to about 40%, about 0.1% to about 40%, about 0.5% to about 30%, about 1% to about 30%, or about 5% to about 20%. In some embodiments, the oxygen content of the first spacer material 741 may be at least about 20 %, about 40%, or about 50% on an atomic basis. In some embodiments, the oxygen content of the first spacer material 741 on an atomic basis may range from 10% to about 70%, about 15% to about 50%, or from about 20% to about 40%. In some embodiments, the silicon content of the first spacer material 741 on an atomic basis may be up to about 50%. In some embodiments, the silicon content of the first spacer material 741 on an atomic basis may be at least about 15%, about 20%, about 25%, or about 30%. In some embodiments, the silicon content of the first spacer material 741 on an atomic basis may range from about 10% to about 50%, about 15% to about 40%, or about 20% to about 35%. In some embodiments, the sulfur content of the first spacer material 741 on an atomic basis may be up to about 40%. In some embodiments, the sulfur content of the first spacer material 741 on an atomic basis may range from about 0.01% to about 40%, about 0.1% to about 40%, about 0.5% to about 30%, or about 1% to about 20%. In some embodiments, the sulfur content of the first spacer material 741 on an atomic basis may be at least about 1%, about 10%, or about 20%.

In some embodiments, the layer of first spacer material 741 may not include an appreciable amount of nitrogen. In some embodiments, the nitrogen content of the first spacer material 741 on an atomic basis may be present at less than about 30%, less than about 20%, less than about 15%, less than about 10%, less than about 5%, less than about 1%, or less than about 0.1%. In some embodiments, the first spacer material 741 does not include nitrogen.

In some embodiments, the deposition of the layer of first spacer material 741 may be performed using a plasma-enhanced atomic layer deposition (PEALD) process. The PEALD process may consist of at least one deposition cycle. Each cycle may begin with exposing the intermediate semiconductor device illustrated in FIG. 23 to a vapor-phase silicon-containing precursor that does not include nitrogen (referred to as the precursor step). This step allows silicon-containing species to adsorb onto the surface of the intermediate semiconductor device.

Following precursor exposure, a purge gas and/or vacuum may be applied to remove any excess silicon precursor and reaction byproducts (referred to as the first purge step). Next, the surface of the intermediate semiconductor device may be exposed to a reactant containing hydrogen-based reactive species generated by plasma (referred to as the reactant step). The plasma energy facilitates the conversion of the adsorbed silicon species into the layer of first spacer material 741, which includes SiCO. Similar to the precursor step, any excess reactant and byproducts may then be removed using a purge gas and/or vacuum (referred to as the second purge step).

These sequential exposure and removal steps form one complete deposition cycle. To achieve the desired thickness and composition of the layer of first spacer material 741, the deposition cycle may be repeated multiple times.

In some embodiments, the silicon-containing precursor must not include nitrogen. In some embodiments, the silicon-containing precursor may not include a halogen. In some embodiments, the silicon-containing precursor may be, for example, bis(triethoxysilyl)ethane (BTESE), 3-methoxypropyltrimethoxysilane (MPTMS), and/or (3-mercaptopropyl)trimethoxysilane. In some embodiments, more than one silicon-containing precursor either simultaneously or in alternating deposition cycles to optimize film properties. In some embodiments, the pulse time for the precursor step may be between about 4 seconds and about 10 seconds.

In some embodiments, the reactant may include hydrogen and is used to generate reactive species via plasma. In some embodiments, the reactant may not include any oxygen. In some embodiments, the reactant may contain a low atomic percentage of oxygen (less than about 50 at % down to less than 0.001 at %). In some embodiments, the reactant may not include nitrogen. In some embodiments, the reactant may contain a low atomic percentage of nitrogen (less than about 25 at % down to less than 0.001 at %). In some alternative embodiments, nitrogen-containing species may be intentionally introduced. In some embodiments, the reactive species generated from the reactant may include hydrogen plasma, hydrogen atoms, hydrogen radicals, and/or hydrogen ions.

In some embodiments, the reactant may be, for example, essentially pure hydrogen gas, a mixture of hydrogen gas and a noble gas, or a mixture of hydrogen gas and nitrogen gas. In some embodiments, the noble gas may include helium, neon, argon, krypton, and xenon. In some embodiments, the atomic percentage of nitrogen of the mixture of hydrogen gas and nitrogen gas may be less than 20%. In some embodiments, the reactant may include compounds having both N and H (like NH₃ and N₂H₄).

In some embodiments, the plasma power for generating the reactive species from the reactant may be between about 5 W and about 5000 W or between about 100 W and about 300 W. In some embodiments, the plasma pulse time may be between about 2 seconds and about 6 seconds, or about 4 seconds. In some embodiments, the generation of the plasma or reactive species in the second reactant step can occur remotely before the reactant contacts the intermediate semiconductor device.

In some embodiments, the purge gas for the first/second purge steps may include, for example, argon, helium, and/or nitrogen. The purpose of the purge gas is to remove unreacted precursors/reactants and byproducts from the reaction chamber after each exposure step. In some embodiments, the purge time may be 0.5 seconds, 4 seconds, or 10 seconds. In some alternative embodiments, a vacuum can be used for the first/second purge step, which might involve evacuating the reaction chamber. In some cases, the first/second purge step may include continuing the flow of the purge gas while stopping the precursor or reactant flow, or even moving the intermediate semiconductor device to a different chamber containing the purge gas or under vacuum.

In some embodiments, the temperature of the PEALD process may be less than 200 °C, 150 °C, 100 °C, 75 °C, or 50 °C. In some embodiments, the pressure of the PEALD process (e.g., for the precursor step and the reactant step) may be between about 6 Torr and about 500 Torr.

The layer of first spacer material 741 including SiCO may exhibit strong chemical resistance. For example, the wet etch rate ratio of the layer of first spacer material 741 to that of thermal silicon oxide may be significantly less than 5, 0.3, or even 0.1. Consequently, the layer of first spacer material 741 may effectively protect the bit line structures 520 during subsequent etching processes, reducing defects such as bit line leakage. As a result, the yield of the semiconductor device 1A may be improved. In addition, the dielectric constant of the first spacer material 741 including SiCO may be less than 5, 4.5, or even 4.4, thereby reducing the parasitic capacitance between adjacent bit line structures 520. As a result, the performance of the semiconductor device 1A may be improved.

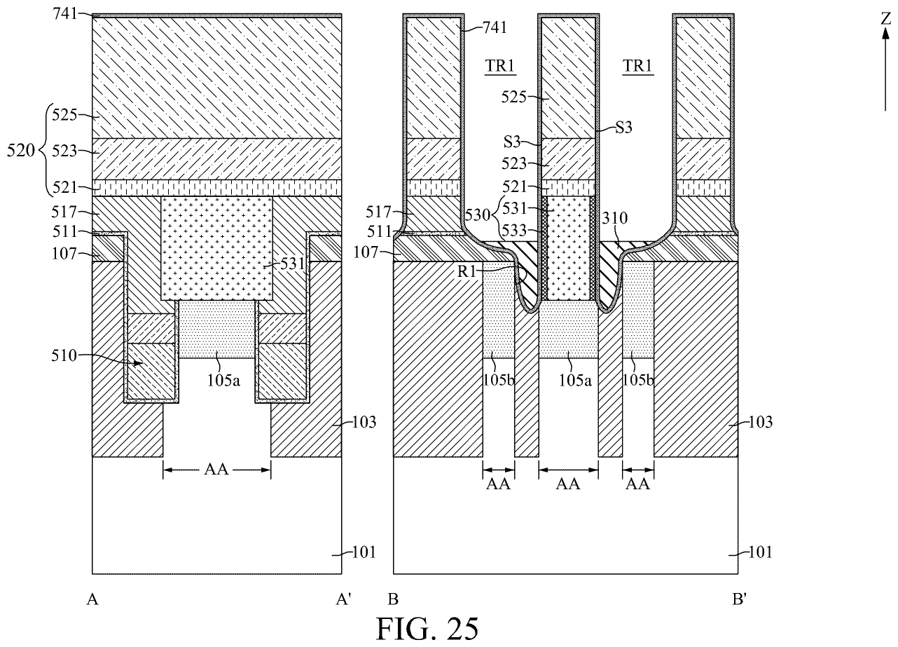

With reference to FIG. 25, the plurality of filling layers 310 may be formed to fill the plurality of recesses R1. In some embodiments, the filling layers 310 may be formed of silicon nitride. These layers may be deposited using two sequential deposition processes: low-pressure chemical vapor deposition (LPCVD) as the first deposition stage, followed by plasma-enhanced chemical vapor deposition (PECVD) as the second deposition stage. In some embodiments, the ratio of the filling layer 310 deposited in the first stage to that deposited in the second stage may be approximately 20:80, 30:70, 40:60, or 50:50. In some embodiments, LPCVD must be performed before PECVD. In some embodiments, both deposition stages may be carried out within the same reaction chamber.

For the first deposition stage (e.g., the LPCVD), the process temperature may be between about 800 °C and about 820 °C The process pressure may be between about 150 millitorr to 250 millitorr. The precursor may include ammonia and dichlorosilane. The ratio of ammonia to dichlorosilane may be maintained at about 4 to about 6. In some embodiments, the hydrogen content of silicon nitride formed by LPCVD may be less than 5 atomic percent.

For the second deposition stage (e.g., the PECVD), the precursor may include silane, ammonia, and nitrogen. The ratio of ammonia to silane may be between about 2 and about 15. The ratio of ammonia to nitrogen may be about 0.3 and about 2.3. The ratio of nitrogen to silane may be between about 5.8 and about 20.8. The flow rate of ammonia may be between about 9600 sccm and about 13500 sccm. The flow rate of nitrogen may be between about 15000 and about 28000 sccm, and the flow rate of silane may be about 1450 sccm and about 2800 sccm. The RF power may be between about 7 MHz and about 13.56 MHz. The process pressure may be between about 0.5Torr and 1.5 Torr, or between about 0.7 Torr and about 1.0 Torr. The process temperature may be between about 120 °C and about 360 °C, or between about 120 °C and about 300 °C

The portion of the filling layers 310 formed by LPCVD (e.g., the lower portion) is denser than that solely formed by PECVD, providing better protection for the underlying layers. In addition, the upper portion of the filling layers 310, which does not require providing such protection for underlying layers, may be deposited using PECVD to reduce overall deposition time. It should be noted that the boundary between the LPCVD-deposited (lower portion) and PECVD-deposited (upper portion) filling layers 310 may not show, as the ratio between LPCVD and PECVD can be tailored to meet different requirements.

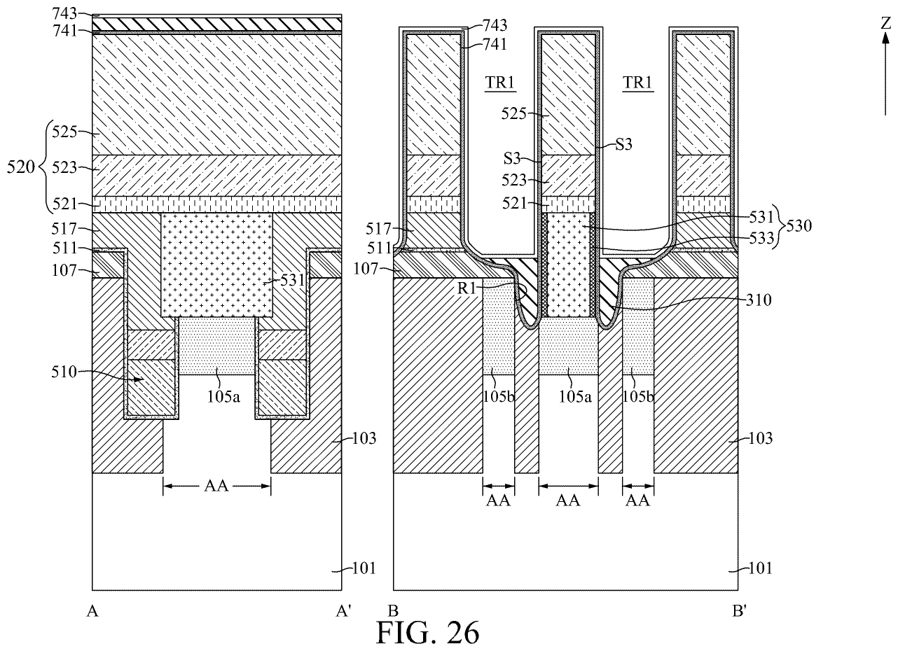

With reference to FIG. 26, the layer of second spacer material 743 may be conformally formed on the layer of first spacer material 741 and on the plurality of filling layers 310. In some embodiments, the second spacer material 743 may be formed of, for example, silicon oxide or other applicable insulating oxides. In some embodiments, the layer of second spacer material 743 may be formed by atomic layer deposition, low-pressure chemical vapor deposition, plasma-enhanced chemical vapor deposition, or other applicable deposition processes.

With reference to FIG. 1 and FIGS. 27 to 29, at step S23, a first spacer etching process may be performed to turn layer of first spacer material 741 into a plurality of inner spacers 211 and turn the layer of second spacer material 743 into a plurality of middle spacers 213, and a plurality of outer spacers 215 may be formed on the plurality of middle spacers 213 to configure a plurality of spacer structures 210.

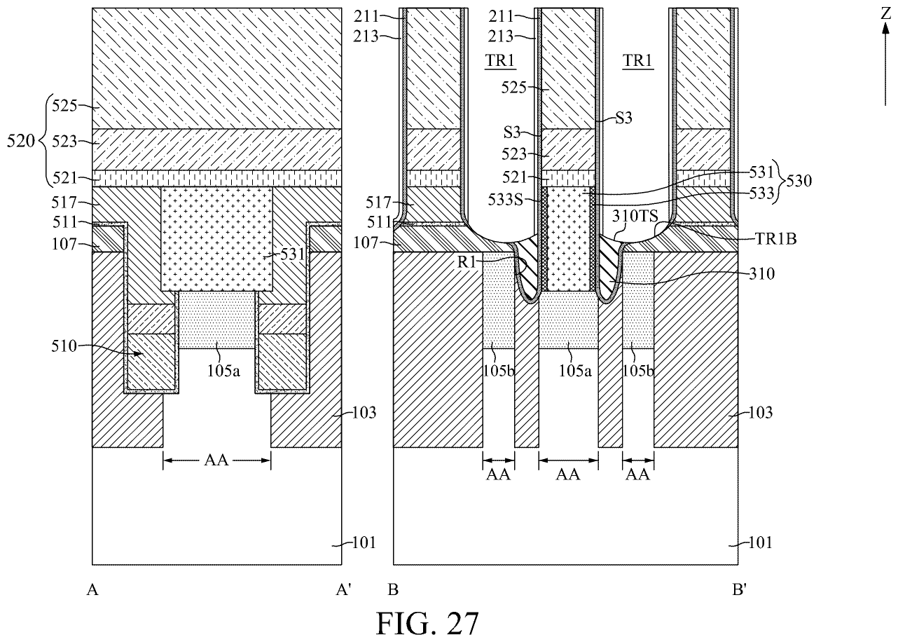

With reference to FIG. 27, the first spacer etching process may be an anisotropic etching process, such as an anisotropic dry etching process. During this process, the plurality of filling layers 310 may be recessed. Additionally, the first spacer material 741 formed on the bit line capping layers 525 and at the bottom TR1B of the trenches TR1 may be removed. The remaining first spacer material 741 may be referred to as the plurality of inner spacers 211.

For brevity, clarity, and convenience of description, only one inner spacer 211 is described. The inner spacer 211 may be conformally disposed on the side S3 of the bit line structure 520. It may extend downward to the substrate 101, following the contour of the recess R1, and cover the sidewall 533S of the contact-isolating spacer 533. Additionally, the inner spacer 211 may surround the filling layer 310 while leaving its top surface 310TS exposed to the trench TR1.

The second spacer material 743 formed on the bit line capping layers 525, on the plurality of filling layers 310, and at the bottom TR1B of the trenches TR1 may be removed during the first spacer etching process. The remaining second spacer material 743 may be referred to as the plurality of middle spacers 213. For brevity, clarity, and convenience of description, only one middle spacer 213 is described. In some embodiments, the middle spacer 213 may be conformally disposed on the inner spacer 211.

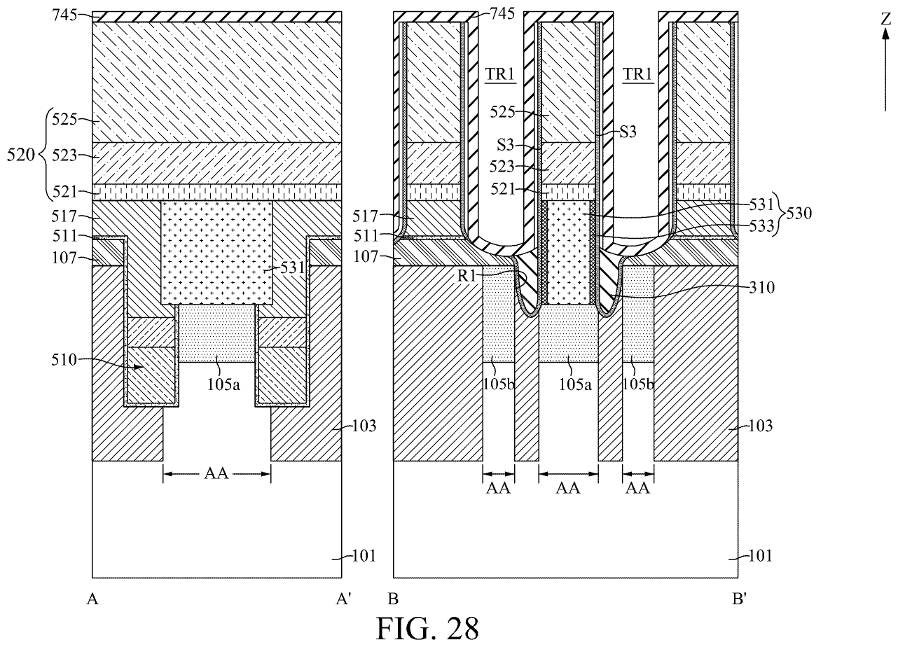

With reference to FIG. 28, a layer of third spacer material 745 may be conformally formed to cover the plurality of bit line structures 520, the plurality of inner spacers 211, the plurality of middle spacers 213, and the plurality of filling layers 310. In some embodiments, the third spacer material 745 may be formed of, for example, silicon nitride or other applicable insulating material. In some embodiments, the layer of third spacer material 745 may be formed by atomic layer deposition, low-pressure chemical vapor deposition, plasma-enhanced chemical vapor deposition, or other applicable deposition processes.

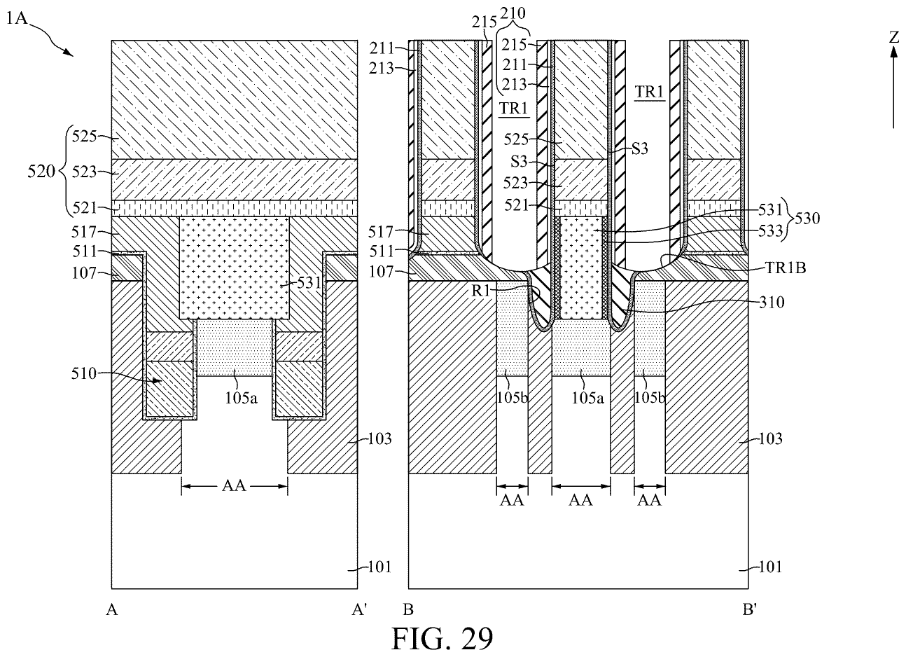

With reference to FIG. 29, a second spacer etching process may be performed to remove the third spacer material 745 on the bit line capping layer 525 and at the bottom TR1B of the trenches TR1 may be removed. The remaining third spacer material 745 may be referred to as the plurality of outer spacers 215. The plurality of outer spacers 215 may be conformally disposed on the plurality of middle spacers 213, respectively and correspondingly. The plurality of outer spacers 215, the plurality of middle spacers 213, and the plurality of inner spacers 211 together configure the plurality of spacer structures 210.

The plurality of inner spacers 211, formed of silicon oxycarbide, may provide enhanced protection for the plurality of bit line structures 520 due to its excellent chemical resistance. This may help reduce defects in the semiconductor device 1A and improve its yield. Additionally, the plurality of filling layers 310, formed through a two-stage deposition process combining LPCVD and PECVD, may offer better protection for the underlying layers without compromising manufacturing efficiency. As a result, both the yield and fabrication efficiency of the semiconductor device 1A may be improved.

One aspect of the present disclosure provides a spacer structure including an inner spacer positioned on a sides of a bit line structure, wherein the inner spacer includes silicon oxycarbide; a middle spacer positioned on the inner spacer; and an outer spacer positioned on the middle spacer.

Another aspect of the present disclosure provides a semiconductor device including a substrate; a bit line structure positioned on the substrate; a spacer structure including an inner spacer conformally positioned on a side of the bit line structure, a middle spacer conformally positioned on the inner spacer, and an outer spacer conformally positioned on the middle spacer. The inner spacer includes silicon oxycarbide.

Another aspect of the present disclosure provides a method for fabricating a semiconductor device including providing a substrate; forming a plurality of bit line contact structures in the substrate; forming a plurality of bit line structures on the plurality of bit line contact structures, wherein the plurality of bit line structures are separated by a plurality of trenches and a plurality of recesses that extend downward from the trenches and are adjacent to the bit line contact structures; conformally forming a layer of first spacer material covering the plurality of bit line structures, the plurality of bit line contact structures, the plurality of trenches, and the plurality of recesses; forming a plurality of filling layers to fill the plurality of recesses; conformally forming a layer of second spacer material covering the layer of first spacer material and the plurality of filling layers; performing a first spacer etching process to turn the layer of first spacer material into a plurality of inner spacers and turn the layer of second spacer material into a plurality of middle spacers; and conformally forming a plurality of outer spacers on the plurality of middle spacers to configure a plurality of spacer structures. The first spacer material includes silicon oxycarbide.

Due to the design of the semiconductor device disclosed herein, the inner spacer 211, formed of silicon oxycarbide, can effectively protect the bit line structures 520 during subsequent etching processes. Its strong chemical resistance helps reduce defects such as bit line leakage, thereby improving the yield of the semiconductor device 1A. Additionally, the low dielectric constant of the silicon oxycarbide inner spacer 211 may reduce parasitic capacitance between adjacent bit line structures 520, enhancing the overall performance of the semiconductor device 1A.

Although the present disclosure and its advantages have been described in detail, it should be understood that various changes, substitutions and alterations can be made herein without departing from the spirit and scope of the disclosure as defined by the appended claims. For example, many of the processes discussed above can be implemented in different methodologies and replaced by other processes, or a combination thereof.

Moreover, the scope of the present application is not intended to be limited to the particular embodiments of the process, machine, manufacture, composition of matter, means, methods and steps described in the specification. As one of ordinary skill in the art will readily appreciate from the disclosure of the present disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, and steps.

What is claimed is:

1. A semiconductor device, comprising
a substrate;
a bit line structure positioned on the substrate; and
a spacer structure comprising:
an inner spacer conformally positioned on a side of the bit line structure;
a middle spacer conformally positioned on the inner spacer; and
an outer spacer conformally positioned on the middle spacer;
wherein the inner spacer comprises silicon oxycarbide.

2. The semiconductor device of claim 1, further comprising a bit line contact structure positioned between the bit line structure and the substrate, wherein the inner spacer extends downward to the substrate and covers the sidewall of the bit line contact structure.

3. The semiconductor device of claim 2, further comprising a filling layer positioned adjacent to the bit line contact structure.

4. The semiconductor device of claim 3, wherein the inner spacer is positioned between the bit line contact structure and the filling layer.

5. The semiconductor device of claim 4, wherein a carbon content of the inner spacer on an atomic basis ranges from about 0.1% to about 40%.

6. The semiconductor device of claim 4, wherein an oxygen content of the inner spacer on an atomic basis is at least about 20 %.

7. The semiconductor device of claim 4, wherein a silicon content of the inner spacer on an atomic basis is at least about 15%.

8. The semiconductor device of claim 4, wherein the middle spacer comprises silicon oxide.

9. The semiconductor device of claim 4, wherein the outer spacer comprises silicon nitride.

10. The semiconductor device of claim 4, wherein the bit line contact structure comprises:
a bit line contact positioned between the bit line structure and the substrate; and
a contact-isolating spacer positioned between the inner spacer and the bit line contact.

11. The semiconductor device of claim 10, wherein the bit line contact comprises tungsten, cobalt, zirconium, tantalum, titanium, aluminum, ruthenium, copper, metal carbides, metal nitrides, transition metal aluminides, or a combination thereof.

12. The semiconductor device of claim 10, wherein the contact-isolating spacer comprises silicon nitride.

13. The semiconductor device of claim 4, wherein the filling layer comprises silicon nitride.
